(19) United States
(12) Patent Application Publication
(10) Pub. No.: US 2025/0316111 A1
(43) Pub. Date: Oct. 9, 2025

(54) DETECTION DEVICE

(71) Applicant: Japan Display Inc., Tokyo (JP)

(72) Inventors: Motochika YUKAWA, Tokyo (JP); Jun NITTA, Tokyo (JP)

(21) Appl. No.: 19/244,073

(22) Filed: Jun. 20, 2025

Related U.S. Application Data
(63) Continuation of application No. PCT/JP2023/045852, filed on Dec. 21, 2023.

(30) Foreign Application Priority Data
Dec. 23, 2022 (JP) 2022-206334

(51) Int. Cl. G06V 40/13; H10F 39/00

(52) U.S. Cl. CPC G06V 40/1318; H10F 39/8037; H10F 39/811

(57) ABSTRACT

According to an aspect, a detection device includes: a substrate; and a plurality of photodiodes in each of which a first electrode, a first buffer layer, a lower active layer, a second buffer layer, a second electrode, a third buffer layer, an upper active layer, a fourth buffer layer, and a third electrode are stacked on the substrate in the order as listed. The first electrode and the third electrode of the photodiode are electrically coupled to each other. Each of the first buffer layer and the fourth buffer layer is one of a hole transport layer and an electron transport layer. Each of the second buffer layer and the third buffer layer is the other of the hole transport layer and the electron transport layer.

### CROSS-REFERENCE TO RELATED APPLICATION

This application claims the benefit of priority from Japanese Patent Application No. 2022-206334 filed on Dec. 23, 2022 and International Patent Application No. PCT/JP2023/045852 filed on Dec. 21, 2023, the entire contents of which are incorporated herein by reference.

### BACKGROUND

### 1. Technical Field

What is disclosed herein relates to a detection device.

### 2. Description of the Related Art

Optical sensors capable of detecting fingerprint patterns and vascular patterns are known (for example, Japanese Patent Application Laid-open Publication No. 2009-032005). Such optical sensors each include a plurality of photodiodes (organic photodiodes (OPDs)) each using an organic semiconductor material as an active layer. As described in International Patent Application Publication No. WO 2020/188959, in each of the photodiodes, for example, a lower electrode, an electron transport layer, the active layer, a hole transport layer, and an upper electrode are stacked in this order. The electron transport layer and the hole transport layer are each also called a buffer layer.

In detection devices having OPDs, the OPDs are desired to be improved in photoelectric conversion efficiency.

### SUMMARY

According to an aspect, a detection device includes: a substrate; and a plurality of photodiodes in each of which a first electrode, a first buffer layer, a lower active layer, a second buffer layer, a second electrode, a third buffer layer, an upper active layer, a fourth buffer layer, and a third electrode are stacked on the substrate in the order as listed. The first electrode and the third electrode of the photodiode are electrically coupled to each other. Each of the first buffer layer and the fourth buffer layer is one of a hole transport layer and an electron transport layer. Each of the second buffer layer and the third buffer layer is the other of the hole transport layer and the electron transport layer.

### BRIEF DESCRIPTION OF THE DRAWINGS

FIG. 1 is a plan view schematically illustrating a detection device according to a first embodiment of the present disclosure;

FIG. 2 is a block diagram illustrating a configuration example of the detection device according to the first embodiment;

FIG. 3 is a circuit diagram illustrating the detection device according to the first embodiment;

FIG. 4 is a plan view schematically illustrating a plurality of photodiodes and potential supply wiring;

FIG. 5 is an enlarged plan view illustrating some of the photodiodes and a portion of the potential supply wiring in FIG. 4;

FIG. 6 is a sectional view along VI-VI′ of FIG. 5;

FIG. 7 is an enlarged sectional view illustrating a portion of each of the photodiodes;

FIG. 8 is a plan view schematically illustrating the photodiodes and the potential supply wiring of a detection device according to a second embodiment of the present disclosure;

FIG. 9 is an enlarged plan view illustrating some of the photodiodes and a portion of the potential supply wiring in FIG. 8;

FIG. 10 is a plan view schematically illustrating the photodiode and potential supply wiring of a detection device according to a third embodiment of the present disclosure; and

FIG. 11 is a plan view illustrating a detection device according to a fourth embodiment of the present disclosure.

### DETAILED DESCRIPTION

The following describes modes (embodiments) for carrying out the present disclosure in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### First Embodiment

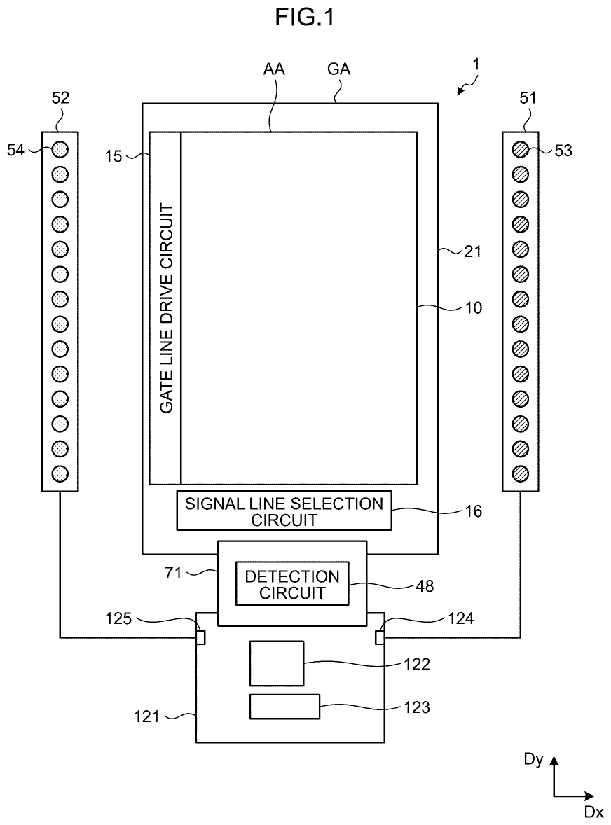

FIG. 1 is a plan view illustrating a detection device according to a first embodiment of the present disclosure. As illustrated in FIG. 1, a detection device 1 includes a substrate 21, a sensor 10, a gate line drive circuit 15, a signal line selection circuit 16, a detection circuit 48, a control circuit 122, a power supply circuit 123, a first light source base member 51, a second light source base member 52, and light sources 53 and 54. The first light source base member 51 is provided with a plurality of the light sources 53. The second light source base member 52 is provided with a plurality of the light sources 54.

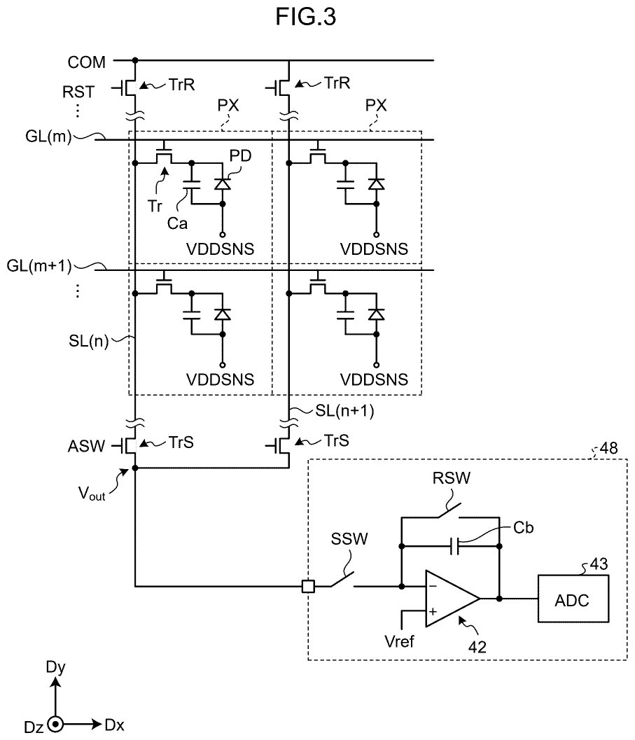

The substrate 21 is electrically coupled to a control substrate 121 through a wiring substrate 71. The wiring substrate 71 is, for example, a flexible printed circuit board or a rigid circuit board. The wiring substrate 71 is provided with the detection circuit 48. The control substrate 121 is provided with the control circuit 122 and the power supply circuit 123. The control circuit 122 is a field-programmable gate array (FPGA), for example. The control circuit 122 supplies control signals to the sensor 10, the gate line drive circuit 15, and the signal line selection circuit 16 to control detection operations of the sensor 10. The control circuit 122 supplies control signals to the light sources 53 and 54 to control lighting and non-lighting of the light sources 53 and 54. The power supply circuit 123 supplies voltage signals including, for example, a sensor power supply signal (sensor power supply voltage) VDDSNS (refer to FIG. 3) to the sensor 10, the gate line drive circuit 15, and the signal line selection circuit 16. The power supply circuit 123 supplies a power supply voltage to the light sources 53 and 54.

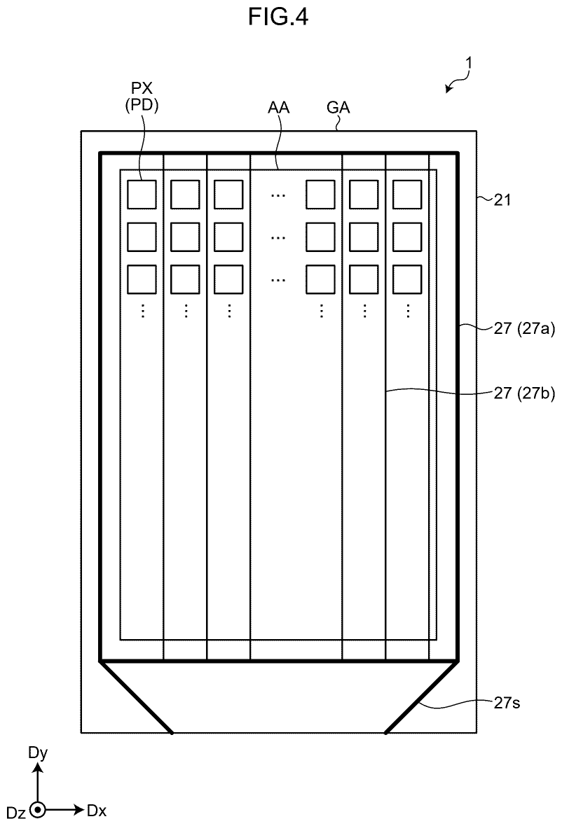

The substrate 21 has a detection area AA and a peripheral area GA. The detection area AA is an area provided with a plurality of photodiodes PD (refer to FIG. 4) included in the sensor 10. The peripheral area GA is an area between the outer perimeter of the detection area AA and the outer edges of the substrate 21 and is an area not provided with the photodiodes PD.

The gate line drive circuit 15 and the signal line selection circuit 16 are provided in the peripheral area GA. Specifically, the gate line drive circuit 15 is provided in an area extending along a second direction Dy in the peripheral area GA. The signal line selection circuit 16 is provided in an area extending along a first direction Dx in the peripheral area GA, and is provided between the sensor 10 and the detection circuit 48.

In the following description, the first direction Dx is one direction in a plane parallel to the substrate 21. The second direction Dy is one direction in the plane parallel to the substrate 21 and is a direction orthogonal to the first direction Dx. The second direction Dy may non-orthogonally intersect the first direction Dx. A third direction Dz is a direction orthogonal to the first direction Dx and the second direction Dy and is a direction normal to a principal surface of the substrate 21. The term “plan view” refers to a positional relation when viewed from a direction orthogonal to the substrate 21.

The first light sources 53 are provided on the first light source base member 51, and arranged along the second direction Dy. The second light sources 54 are provided on the second light source base member 52, and arranged along the second direction Dy. The first light source base member 51 and the second light source base member 52 are electrically coupled, through respective terminals 124 and 125 provided on the control substrate 121, to the control circuit 122 and the power supply circuit 123.

For example, inorganic light-emitting diodes (LEDs) or organic electroluminescent (EL) diodes (organic light-emitting diodes (OLEDs)) are used as the light sources 53 and 54. The light sources 53 and 54 emit light having different wavelengths from each other.

First light emitted from the light sources 53 is mainly reflected on a surface of an object to be detected, such as a finger, and enters the sensor 10. As a result, the sensor 10 can detect a fingerprint by detecting a shape of asperities on the surface of the finger or the like. Second light emitted from the light sources 54 is mainly reflected in the finger or the like, or transmitted through the finger or the like, and enters the sensor 10. As a result, the sensor 10 can detect information on a living body in the finger or the like. Examples of the information on the living body include pulse waves, pulsation, and a vascular image of the finger or a palm. That is, the detection device 1 may be configured as a fingerprint detection device to detect a fingerprint or a vein detection device to detect a vascular pattern of, for example, veins.

The arrangement of the light sources 53 and 54 illustrated in FIG. 1 is merely an example, and can be changed as appropriate. The detection device 1 is provided with a plurality of types of the light sources 53 and 54 as light sources. However, the light sources are not limited thereto, and may be of one type. For example, the light sources 53 and 54 may be arranged on each of the first and the second light source base members 51 and 52. The light sources 53 and 54 may be provided on one light source base member, or three or more light source base members. Alternatively, only at least one light source needs to be disposed.

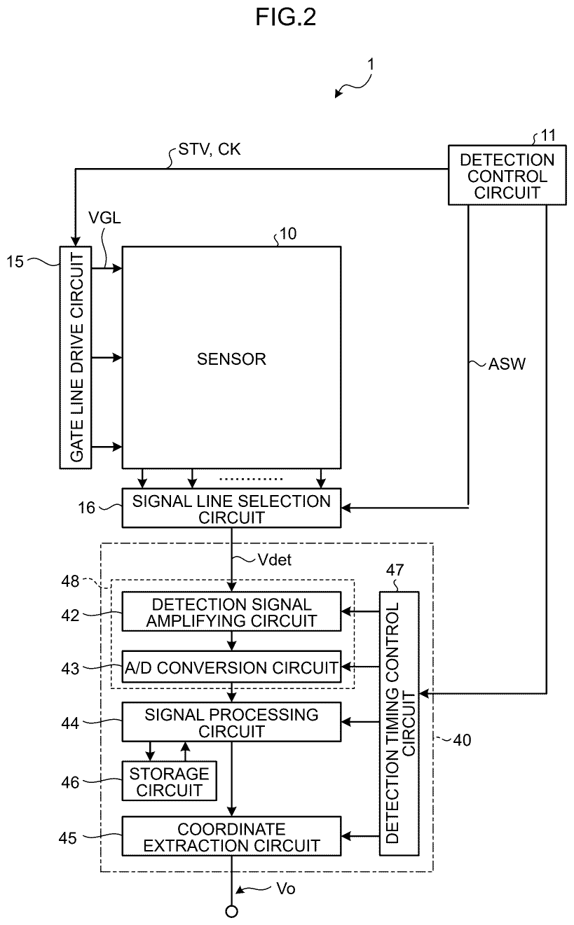

FIG. 2 is a block diagram illustrating a configuration example of the detection device according to the first embodiment. As illustrated in FIG. 2, the detection device 1 further includes a detection control circuit 11 and a detector (detection signal processing circuit) 40. The control circuit 122 includes one, some, or all functions of the detection control circuit 11. The control circuit 122 also includes one, some, or all functions of the detector 40 other than those of the detection circuit 48.

The sensor 10 includes the photodiodes PD. Each of the photodiodes PD included in the sensor 10 outputs an electrical signal corresponding to light received by the photodiode PD as a detection signal Vdet to the signal line selection circuit 16. The sensor 10 performs the detection in response to a gate drive signal VGL supplied from the gate line drive circuit 15.

The detection control circuit 11 supplies respective control signals to the gate line drive circuit 15, the signal line selection circuit 16, and the detector 40 to control operations of these components. The detection control circuit 11 supplies various control signals including, for example, a start signal STV and a clock signal CK to the gate line drive circuit 15. The detection control circuit 11 also supplies various control signals including, for example, a selection signal ASW to the signal line selection circuit 16. The detection control circuit 11 also supplies various control signals to the light sources 53 and 54 to control the lighting and non-lighting of the respective light sources 53 and 54.

The gate line drive circuit 15 drives a plurality of gate lines GL (refer to FIG. 3) based on the various control signals. The gate line drive circuit 15 sequentially or simultaneously selects the gate lines GL, and supplies the gate drive signals VGL to the selected gate lines GL. Through this operation, the gate line drive circuit 15 selects the photodiodes PD coupled to the gate lines GL.

The signal line selection circuit 16 includes a switch circuit that sequentially or simultaneously selects a plurality of signal lines SL (refer to FIG. 3). The signal line selection circuit 16 is a multiplexer, for example. The signal line selection circuit 16 couples the selected signal lines SL to the detection circuit 48 based on the selection signal ASW supplied from the detection control circuit 11. Through this operation, the signal line selection circuit 16 outputs the detection signal Vdet of the photodiode PD to the detector 40.

The detector 40 includes the detection circuit 48, a signal processing circuit 44, a coordinate extraction circuit 45, a storage circuit 46, and a detection timing control circuit 47. The detection timing control circuit 47 controls the detection circuit 48, the signal processing circuit 44, and the coordinate extraction circuit 45 so as to operate in synchronization with one another based on a control signal supplied from the detection control circuit 11.

The detection circuit 48 is an analog front-end (AFE) circuit, for example. The detection circuit 48 is a signal processing circuit having functions of at least a detection signal amplifying circuit 42 and an analog-to-digital (A/D) conversion circuit 43. The detection signal amplifying circuit 42 amplifies the detection signal Vdet. The A/D conversion circuit 43 converts analog signals output from the detection signal amplifying circuit 42 into digital signals.

The signal processing circuit 44 detects predetermined physical quantities received by the sensor 10 based on output signals of the detection circuit 48. The signal processing circuit 44 is a logic circuit. The signal processing circuit 44 can detect the asperities on the surface of the finger or the palm based on the signals from the detection circuit 48 when the finger is in contact with or in proximity to a detection surface. The signal processing circuit 44 can detect the information on the living body based on the signals from the detection circuit 48. Examples of the information on the living body include the vascular image, the pulse waves, the pulsation, and a blood oxygen level of the finger or the palm.

The storage circuit 46 temporarily stores therein signals calculated by the signal processing circuit 44. The storage circuit 46 may be, for example, a random-access memory (RAM) or a register circuit.

The coordinate extraction circuit 45 obtains detected coordinates of the asperities on the surface of the finger or the like when contact or proximity of the finger is detected by the signal processing circuit 44. The coordinate extraction circuit 45 also obtains detected coordinates of blood vessels in the finger or the palm. The coordinate extraction circuit 45 is a logic circuit. The coordinate extraction circuit 45 combines the detection signals Vdet output from the photodiodes PD of the sensor 10 to generate two-dimensional information indicating the shape of the asperities on the surface of the finger or the like and two-dimensional information indicating the shape of the blood vessels in the finger or the palm. The coordinate extraction circuit 45 may output the detection signals Vdet as sensor output voltages Vo instead of calculating the detected coordinates.

FIG. 3 is a circuit diagram illustrating the detection device according to the first embodiment. FIG. 3 also illustrates a circuit configuration of the detection circuit 48. As illustrated in FIG. 3, a sensor pixel PX includes the photodiode PD, a capacitive element Ca, and a drive transistor Tr. The capacitive element Ca is capacitance (sensor capacitance) generated in the photodiode PD and is equivalently coupled in parallel to the photodiode PD.

The drive transistors Tr are provided correspondingly to the photodiodes PD. Each of the drive transistors Tr is configured as a thin-film transistor, and in this example, configured as an n-channel metal oxide semiconductor (MOS) thin-film transistor (TFT).

FIG. 3 illustrates two gate lines GL(m) and GL(m+1) arranged in the second direction Dy among the gate lines GL. FIG. 3 also illustrates two signal lines SL(n) and SL(n+1) arranged in the first direction Dx among the signal lines SL. The sensor pixel PX is an area surrounded by the gate lines GL and the signal lines SL.

The gate lines GL each extend in the first direction Dx and are arranged with gaps interposed therebetween in the second direction Dy. The signal lines SL each extend in the second direction Dy and are arranged with gaps interposed therebetween in the first direction Dx. The photodiodes PD (sensor pixels PX) are each provided in an area surrounded by two of the gate lines GL and two of the signal lines SL.

Each of the gate lines GL is coupled to the gates of the drive transistors Tr arranged in the first direction Dx. Each of the signal lines SL is coupled to either the sources or the drains of the drive transistors Tr arranged in the second direction Dy. The other of the sources and the drains of the drive transistors Tr are each coupled to the cathode of the photodiode PD and the capacitive element Ca.

The anode of the photodiode PD is supplied with the sensor power supply signal VDDSNS from the power supply circuit 123 (refer to FIG. 1). The signal line SL and the capacitive element Ca are supplied with a sensor reference voltage COM serving as an initial potential of the signal line SL and the capacitive element Ca from the power supply circuit 123 via a reset transistor TrR.

When the sensor pixel PX is irradiated with light in an exposure period, a current corresponding to the amount of the light flows through the photodiode PD. As a result, an electric charge is stored in the capacitive element Ca. When the drive transistor Tr is turned on in a readout period, a current corresponding to the electric charge stored in the capacitive element Ca flows through the signal line SL. The signal line SL is coupled to the detection circuit 48 via an output transistor TrS of the signal line selection circuit 16. Thus, the detection device 1 can detect a signal corresponding to the amount of the light received by the photodiode PD for each sensor pixel PX.

During the readout period, a switch SSW is turned on to couple the detection circuit 48 to the signal line SL. The detection signal amplifying circuit 42 of the detection circuit 48 converts a current or an electric charge supplied from the signal line SL into a voltage corresponding thereto. A reference potential (Vref) having a fixed potential is supplied to a non-inverting input portion (+) of the detection signal amplifying circuit 42, and the signal line SL is coupled to an inverting input portion (−) of the detection signal amplifying circuit 42. In the present embodiment, the same signal as the sensor reference voltage COM is supplied as the reference potential (Vref) voltage. The control circuit 122 (refer to FIG. 1) calculates, as each of the sensor output voltages Vo, the difference between the detection signal Vdet when the photodiode PD is irradiated with light and the detection signal Vdet when the photodiode PD is not irradiated with light. The detection signal amplifying circuit 42 includes a capacitive element Cb and a reset switch RSW. During the reset period, the reset switch RSW is turned on to reset the electric charge of the capacitive element Cb.

The drive transistor Tr is not limited to an n-type TFT and may be configured as a p-type TFT. The pixel circuit of the sensor pixel PX illustrated in FIG. 3 is merely exemplary. The sensor pixel PX may include one photodiode PD provided with a plurality of transistors.

FIG. 4 is a plan view schematically illustrating the photodiodes and potential supply wiring. As illustrated in FIG. 4, the photodiodes PD (sensor pixels PX) are arranged in a matrix having a row-column configuration in the detection area AA of the substrate 21. The detection device 1 further includes potential supply wiring 27 that is provided on the substrate 21 and supplies a predetermined potential to the photodiodes PD. The predetermined potential is, for example, the sensor power supply signal VDDSNS (refer to FIG. 3).

In more detail, the potential supply wiring 27 includes peripheral line 27a, first extension lines 27b, and coupling lines 27s. The peripheral line 27a is provided in the peripheral area GA of the substrate 21 so as to surround the detection area AA. In plan view, the first extension lines 27b are provided overlapping the detection area AA and extend in the second direction Dy. One end and the other end in the second direction Dy of each of the first extension lines 27b are coupled to respective portions of the peripheral line 27a extending in the first direction Dx in the peripheral area GA. The first extension lines 27b are each coupled to the photodiodes PD arranged in the second direction Dy. The coupling lines 27s are provided in the peripheral area GA of the substrate 21 and couples the peripheral line 27a to external circuits (control circuit 122 and power supply circuit 123 (refer to FIG. 1)).

The configuration of the potential supply wiring 27 is merely exemplary and can be changed as appropriate. For example, the peripheral line 27a is provided continuously around the four sides of the detection area AA, but is not limited to this configuration, and may be provided so as to be separated into a plurality of wiring lines. Alternatively, the peripheral line 27a need not be provided in an area along at least one side of the detection area AA.

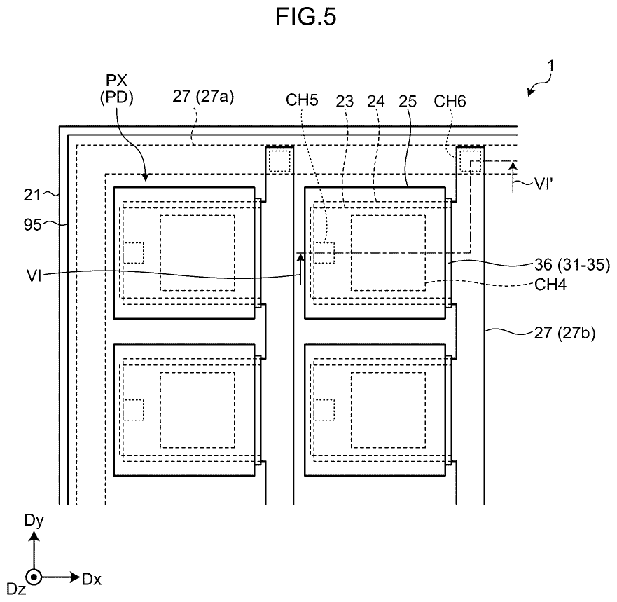

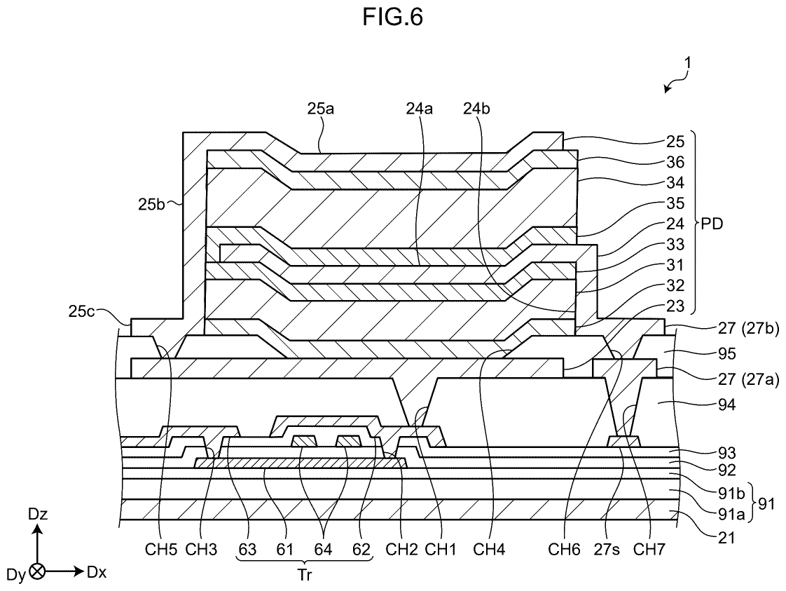

The following describes a configuration of the photodiode PD. FIG. 5 is an enlarged plan view illustrating some of the photodiodes and a portion of the potential supply wiring in FIG. 4. As illustrated in FIG. 5, the photodiode PD includes a first electrode 23, a second electrode 24, and a third electrode 25. In plan view, the first electrode 23, the second electrode 24, and the third electrode 25 are arranged overlapping each other. A lower active layer 31, a first buffer layer 32, a second buffer layer 33, an upper active layer 34, a third buffer layer 35, and a fourth buffer layer 36 are provided between layers of the first, the second, and the third electrodes 23, 24, and 25. Each of the electrodes, each of the active layers, and each of the buffer layers included in the photodiode PD are provided so as to be separated for each of the photodiodes PD. The multilayered configuration of the photodiode PD will be described later with reference to FIG. 6.

The first extension line 27b of the potential supply wiring 27 extends along the photodiodes PD arranged in the second direction Dy and is coupled to the second electrodes 24 of the photodiodes PD arranged in the second direction Dy. The first extension line 27b of the potential supply wiring 27 is coupled to the peripheral line 27a through a contact hole CH6.

FIG. 6 is a sectional view along VI-VI′ of FIG. 5. As illustrated in FIG. 6, in the detection device 1, the drive transistor Tr, insulating films 94 and 95, and the photodiode PD are stacked in this order on the substrate 21. The detection device 1 also includes an undercoat film 91, a gate insulating film 92, and an interlayer insulating film 93 as a plurality of insulating films stacked on the substrate 21.

In the following description, a direction from the substrate 21 toward the third electrode 25 of the photodiode PD in a direction orthogonal to the surface of the substrate 21 is referred to as “upper side” or simply “above”. A direction from the third electrode 25 of the photodiode PD toward the substrate 21 is referred to as “lower side” or simply “below”.

The substrate 21 is an insulating substrate, and is made using, for example, a glass substrate of quartz, alkali-free glass, or the like. The substrate 21 is not limited to having a flat plate shape and may have a curved surface. In this case, the substrate 21 may be made of a film-like resin material.

The undercoat film 91 is provided so as to cover the upper surface of the substrate 21. The undercoat film 91 has, for example, a two-layer stacked structure including insulating films 91a and 91b. The undercoat film 91 is formed, for example, of an inorganic insulating film, such as a silicon nitride (SiN) film or a silicon oxide (SiO₂) film. The configuration of the undercoat film 91 is not limited to that illustrated in FIG. 6. For example, the undercoat film 91 may be a single layer film or three or more stacked layers.

The drive transistor Tr is provided in an area overlapping the first electrode 23 of the photodiode PD in plan view. Specifically, the drive transistor Tr includes a semiconductor layer 61, a source electrode 62, a drain electrode 63, and a gate electrode 64.

The semiconductor layer 61 is provided on the undercoat film 91. The gate insulating film 92 is provided on the undercoat film 91 so as to cover the semiconductor layer 61. The gate insulating film 92 is, for example, an inorganic insulating film such as a silicon oxide film. The gate electrode 64 is provided on the gate insulating film 92.

In the example illustrated in FIG. 6, the drive transistor Tr has a top-gate structure. However, the drive transistor Tr is not limited thereto and may have a bottom-gate structure, or a structure in which the gate electrodes 64 are respectively provided on the upper side and lower side of the semiconductor layer 61.

The interlayer insulating film 93 is provided on the gate insulating film 92 so as to cover the gate electrode 64. The interlayer insulating film 93 has, for example, a multilayered structure of a silicon nitride film and a silicon oxide film. The source electrode 62 and the drain electrode 63 are provided on the interlayer insulating film 93. The source electrode 62 is coupled to a source region of the semiconductor layer 61 through a contact hole CH2 provided in the gate insulating film 92 and the interlayer insulating film 93. The drain electrode 63 is coupled to a drain region of the semiconductor layer 61 through a contact hole CH3 provided in the gate insulating film 92 and the interlayer insulating film 93.

The insulating film 94 is provided on the interlayer insulating film 93 so as to cover the source electrode 62 and the drain electrode 63 of the drive transistor Tr. The insulating film 94 is an organic planarizing film formed of an organic insulating material. In the present embodiment, a contact hole CH1 in the organic insulating film 94 is provided in an area overlapping the source electrode 62 in plan view. The first electrode 23 of the photodiode PD is electrically coupled to the source electrode 62 at the bottom of the contact hole CH1.

The photodiode PD and the peripheral line 27a of the potential supply wiring 27 are provided on the insulating film 94. In more detail, the photodiode PD includes the first electrode 23, the first buffer layer 32, the lower active layer 31, the second buffer layer 33, and the second electrode 24, the third buffer layer 35, the upper active layer 34, the fourth buffer layer 36, and the third electrode 25. In the photodiode PD, the first electrode 23, the first buffer layer 32, the lower active layer 31, the second buffer layer 33, and the second electrode 24, the third buffer layer 35, the upper active layer 34, the fourth buffer layer 36, and the third electrode 25 are stacked in this order in the direction orthogonal to the substrate 21.

The photodiode PD of the present embodiment is an organic photodiode (OPD) including the lower active layer 31 and the upper active layer 34 made of an organic semiconductor.

The first electrode 23 and the third electrode 25 are cathode electrodes of the photodiode PD and are formed of a light-transmitting conductive material, such as indium tin oxide (ITO) or indium zinc oxide (IZO). However, at least one of the first electrode 23 and the third electrode 25 only needs to be formed of a light-transmitting conductive material. The other of the first electrode 23 and the third electrode 25 may be formed of a metal material or an alloy material of molybdenum (Mo) or aluminum (Al), for example. Alternatively, the other of the first electrode 23 and the third electrode 25 may be a multilayered film formed by stacking these metal materials.

For example, if the detection device 1 is configured as a top-illuminated device, the third electrode 25 is formed of a light-transmitting conductive material and the first electrode 23 is formed of a non-light-transmitting conductive material. If the detection device 1 is configured as a bottom-illuminated device, the first electrode 23 is formed of a light-transmitting conductive material and the third electrode 25 is formed of a non-light-transmitting conductive material.

The first electrode 23 is a lower electrode of the photodiode PD and is provided on the insulating film 94. The insulating film 95 is provided on the insulating film 94 so as to cover the first electrode 23 and the peripheral line 27a. The insulating film 95 is a barrier film formed of an inorganic insulating material, such as a silicon nitride (SiN) film. The organic insulating film 95 may alternatively be formed of an organic insulating material. The peripheral line 27a is provided in the same layer as the first electrode 23. The peripheral line 27a is coupled to the coupling lines 27s through a contact hole CH7 provided in the insulating film 94. However, the peripheral line 27a is not limited to the configuration of being provided in the same layer as the first electrode 23 and may be provided in a layer different from the first electrode 23.

The third electrode 25 is an upper electrode of the photodiode PD, and in the example illustrated in FIG. 6, located in the uppermost layer of the photodiode PD. The third electrode 25 has an overlapping portion 25a, a side 25b, and a rib 25c. The overlapping portion 25a is provided on the fourth buffer layer 36. An end of the overlapping portion 25a opposite to the side 25b is located more inward than an end in the first direction Dx of the fourth buffer layer 36. This configuration can prevent or reduce occurrences of short circuits between the overlapping portion 25a of the third electrode 25 and the second electrode 24, at a portion located more outward than the end in the first direction Dx of the fourth buffer layer 36.

The side 25b extends in the third direction Dz along portions of side surfaces of the first buffer layer 32, the lower active layer 31, the second buffer layer 33, the third buffer layer 35, the upper active layer 34, and the fourth buffer layer 36. The upper end of the side 25b is coupled to the overlapping portion 25a, and the lower end of the side 25b is coupled to the rib 25c.

The rib 25c is provided on the insulating film 95 and is coupled to the first electrode 23 through a contact hole CH5 provided in the insulating film 95. With this configuration, the third electrode 25 is electrically coupled to the first electrode 23. The first electrode 23 and the third electrode 25 are electrically coupled to the drive transistor Tr through the contact hole CH1.

The second electrode 24 is located between the first electrode 23 and the third electrode 25 in the third direction Dz. The second electrode 24 is an anode electrode of the photodiode PD and is formed of, for example, a light-transmitting conductive material, such as ITO. The second electrode 24 has an interlayer 24a and a side 24b. The interlayer 24a is provided between the second buffer layer 33 and the third buffer layer 35 in the third direction Dz.

An end of the interlayer 24a opposite to the side 24b is located so as to be separated from the side 25b of the third electrode 25 in the first direction Dx. The second buffer layer 33 and the third buffer layer 35 are provided between the interlayer 24a of the second electrode 24 and the side 25b of the third electrode 25. The second buffer layer 33 and the third buffer layer 35 have sheet resistance values that can prevent or reduce occurrences of short circuits between the interlayer 24a of the second electrode 24 and the side 25b of the third electrode 25. As a result, occurrences of short circuits in the first direction Dx between the interlayer 24a of the second electrode 24 and the side 25b of the third electrode 25 can be prevented or reduced.

The side 24b extends in the third direction Dz so as to cover portions of side surfaces of the first buffer layer 32, the lower active layer 31, and the second buffer layer 33. The side 24b of the second electrode 24 is located opposite the side 25b of the third electrode 25 in the first direction Dx. The upper end of the side 24b is coupled to the interlayer 24a, and the lower end of the side 24b is coupled to the first extension line 27b of the potential supply wiring 27. The first extension line 27b is coupled to the peripheral line 27a through the contact hole CH6 provided in the insulating film 95. With this configuration, the second electrode 24 is electrically coupled to the potential supply wiring 27.

The first buffer layer 32, the lower active layer 31, and the second buffer layer 33 are stacked between the first electrode 23 and the second electrode 24. The third buffer layer 35, the upper active layer 34, and the fourth buffer layer 36 are stacked between the second electrode 24 and the third electrode 25. In the present embodiment, the second electrode 24 is provided so as to serve as an anode electrode for each of a lower portion of the photodiode (first buffer layer 32, lower active layer 31, and second buffer layer 33) and an upper portion of the photodiode (third buffer layer 35, upper active layer 34 and fourth buffer layer 36).

In more detail, the first buffer layer 32 is provided on the insulating film 95. The insulating film 95 has a contact hole CH4 in an area overlapping the first electrode 23 in plan view. The first buffer layer 32 is in direct contact with the first electrode 23 through the contact hole CH4 in the insulating film 95. The lower active layer 31 is provided between the first buffer layer 32 and the second buffer layer 33 in the third direction Dz. The second buffer layer 33 is provided between the lower active layer 31 and the second electrode 24 in the third direction Dz and is in direct contact with the lower surface of the interlayer 24a of the second electrode 24.

The third buffer layer 35 is provided between the second electrode 24 and the upper active layer 34 in the third direction Dz and is in direct contact with the upper surface of the interlayer 24a of the second electrode 24. The upper active layer 34 is provided between the third buffer layer 35 and the fourth buffer layer 36 in the third direction Dz. The fourth buffer layer 36 is provided between the upper active layer 34 and the third electrode 25 in the third direction Dz and is in direct contact with the lower surface of the overlapping portion 25a of the third electrode 25.

The lower and the upper active layers 31 and 34 change in characteristics (for example, voltage-current characteristics and resistance values) according to light emitted thereto. An organic material is used as a material of each of the lower and the upper active layers 31 and 34. Specifically, the lower and the upper active layers 31 and 34 each have a bulk heterostructure containing a mixture of a p-type organic semiconductor and an n-type fullerene derivative ((6,6)-phenyl-C₆₁-butyric acid methyl ester (PCBM)) that is an n-type organic semiconductor. As the lower and the upper active layers 31 and 34, low-molecular-weight organic materials can be used including, for example, fullerene (C₆₀), phenyl-C₆₁-butyric acid methyl ester (PCBM), copper phthalocyanine (CuPc), fluorinated copper phthalocyanine (F₁₆CuPc), 5,6,11,12-tetraphenyltetracene (rubrene), and perylene diimide (PDI) (derivative of perylene).

The lower and the upper active layers 31 and 34 can be formed by a vapor deposition process (dry process) using any of the low-molecular-weight organic materials listed above. In this case, the lower and the upper active layers 31 and 34 may each be, for example, a multilayered film of p CuPc and F₁₆CuPc, or a multilayered film of rubrene and C₆₀. The lower and the upper active layers 31 and 34 can also be formed by a coating process (wet process). In this case, the lower and the upper active layers 31 and 34 are each made using a material obtained by combining any of the above-listed low-molecular-weight organic materials with a high-molecular-weight organic material. As the high-molecular-weight organic material, for example, poly(3-hexylthiophene) (P3HT) and F8-alt-benzothiadiazole (F8BT) can be used. The lower active layer 31 can be a film made of a mixture of P3HT and PCBM, or a film made of a mixture of F8BT and PDI.

The lower and the upper active layers 31 and 34 are not limited to the bulk heterostructure and may have a positive-intrinsic-negative (PIN) structure. The lower and the upper active layers 31 and 34 are formed of the same material. However, the lower and the upper active layers 31 and 34 are not limited to being formed of the same material and may be formed of different materials. If materials having different wavelength characteristics are used as the lower and the upper active layers 31 and 34, the lower and the upper active layers 31 and 34 are sensitive to light in different wavelength regions.

The first and the fourth buffer layers 32 and 36 are electron transport layers, and the second and the third buffer layers 33 and 35 are hole transport layers. The first buffer layer 32 and the second buffer layer 33 are provided to facilitate holes and electrons generated in the lower active layer 31 to reach the first electrode 23 or the second electrode 24. In the same way, the third buffer layer 35 and the fourth buffer layer 36 are provided to facilitate holes and electrons generated in the upper active layer 34 to reach the second electrode 24 or the third electrode 25.

Polyethylenimine ethoxylated (PEIE) is used as a material of the first and the fourth buffer layers 32 and 36 (electron transport layers). The material of the second and the third buffer layers 33 and 35 (hole transport layers) is a metal oxide layer. For example, tungsten oxide (WO3) or molybdenum oxide is used as the metal oxide layer.

The first and the fourth buffer layers 32 and 36 are formed of the same material and have the same thickness. The second and the third buffer layers 33 and 35 are also formed of the same material and have the same thickness. However, the present disclosure is not limited thereto. The first and the fourth buffer layers 32 and 36 may be formed of different materials and have different thicknesses. The second and the third buffer layers 33 and 35 may also be formed of different materials and have different thicknesses.

The materials and the manufacturing methods of the lower and the upper active layers 31 and 34, the first and the second buffer layers 32 and 33, and the third and the fourth buffer layers 35 and 36 are merely exemplary, and other materials and manufacturing methods may be used. For example, each of the first and the second buffer layers 32 and 33 and the third and the fourth buffer layers 35 and 36 is not limited to a single-layer film and may be formed as a multilayered film.

The second buffer layer 33 and the third buffer layer 35 are provided so as to overlap each other in plan view between an end of the second electrode 24 (interlayer 24a) and the side 25b of the third electrode 25 that are adjacent in the first direction Dx. An area where the second buffer layer 33 is in contact with the third buffer layer 35 is smaller than the area of the photodiode PD in plan view. Therefore, the leakage between the buffer layers is sufficiently small. However, insulating films may be formed between the second buffer layer 33 and the third buffer layer 35, and on the sides of the buffer layers and the active layers, as required.

Although not illustrated in the drawings, a sealing film is provided to cover the photodiodes PD. An inorganic insulating film such as a silicon nitride film or an aluminum oxide film or a resin film such as an acrylic film is used as the sealing film. The sealing film is not limited to a single layer and may be a multilayered film having two or more layers obtained by combining the inorganic film with the resin film mentioned above. The sealing film seals the photodiode PD well, and thus can reduce moisture entering the photodiode PD from the upper surface side thereof.

The configuration of the photodiode PD illustrated in FIG. 6 is merely exemplary and can be changed as appropriate. For example, the first electrode 23 and the third electrode 25 may be anode electrodes of the photodiode PD, and the second electrode 24 may be the cathode electrode of the photodiode PD. In this case, the first and the fourth buffer layers 32 and 36 are hole transport layers, and the second and the third buffer layers 33 and 35 are electron transport layers.

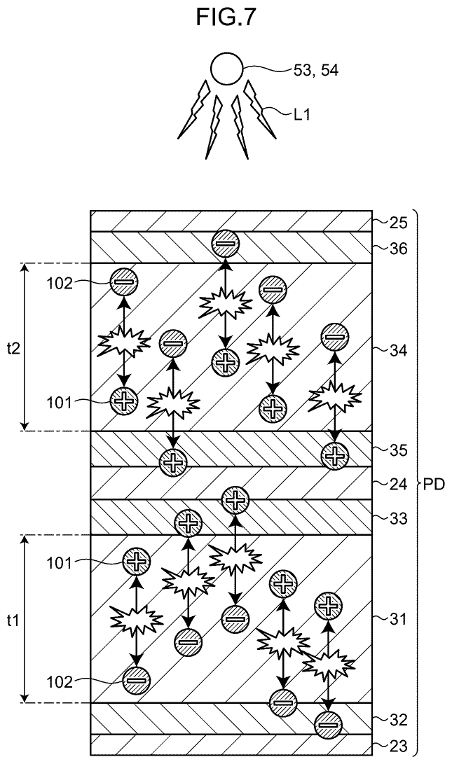

FIG. 7 is an enlarged sectional view illustrating a portion of the photodiode. As illustrated in FIG. 7, light L1 emitted from the light sources 53 and 54 is reflected or transmitted by the object to be detected and enters the third electrode 25 side of the photodiode PD. The third electrode 25 is formed of a light-transmitting conductive material. The light L1 transmitted through the third electrode 25 is applied to the upper active layer 34. Carriers (holes 101 and electrons 102) are generated in the upper active layer 34 according to the emitted light L1. The holes 101 flow through the third buffer layer 35 to the second electrode 24. The electrons 102 flow through the fourth buffer layer 36 to the third electrode 25.

The light L1 transmitted through the upper active layer 34 and the second electrode 24 is emitted to the lower active layer 31. Carriers (holes 101 and electrons 102) are generated in the lower active layer 31 according to the emitted light L1. The holes 101 flow through the second buffer layer 33 to the second electrode 24. The electrons 102 flow through the first buffer layer 32 to the first electrode 23. Therefore, the detection device 1 of the present embodiment can more improve the photoelectric conversion efficiency than a configuration provided with only one of the upper active layer 34 and the lower active layer 31.

In more detail, in the present embodiment, the lower active layer 31 having a thickness tl and the upper active layer 34 having a thickness t2 are stacked with the second buffer layer 33, the second electrode 24, and the third buffer layer 35 interposed therebetween. As a result, the carriers generated in each of the lower and the upper active layers 31 and 34 travel shorter distances to reach the respective buffer layers than in a case where a single active layer having a thickness t1+t2 is provided. Therefore, the configuration of the present embodiment can reduce recombination of the carriers moving through each of the lower and the upper active layers 31 and 34 as compared with in the case where a single active layer having a thickness t1+t2 is provided. Thus, the detection device 1 of the present embodiment can improve the photoelectric conversion efficiency.

In addition, in the present embodiment, compared with the case where the single active layer having the thickness t1+t2 is provided, the lower and the upper active layers 31 and 34 need not be thickened in the respective manufacturing processes thereof, thereby reducing occurrence of structural defect in the lower and the upper active layers 31 and 34. Therefore, in the present embodiment, occurrences of reverse reactions (recombination of holes 101 and electrons 102 immediately after their separation) caused by the structural defects in the lower and the upper active layers 31 and 34 can be reduced.

In the example illustrated in FIG. 7, the thickness t1 of the lower active layer 31 is equal to the thickness t2 of the upper active layer 34. However, the thicknesses thereof are not limited to this example. The thickness t1 of the lower active layer 31 may differ from the thickness t2 of the upper active layer 34. Specifically, if the third electrode 25 has a light-transmitting property and the photodiode PD is configured as a top-illuminated device, the thickness t2 of the upper active layer 34 is larger than the thickness t1 of the lower active layer 31. This configuration allows the light L1 incident from the third electrode 25 side to efficiently generate carriers in the upper active layer 34 of the photodiode PD.

If, unlike in the example illustrated in FIG. 7, the first electrode 23 has a light-transmitting property and the photodiode PD is configured as a bottom-illuminated device, the thickness t1 of the lower active layer 31 is larger than the thickness t2 of the upper active layer 34. This configuration allows the light L1 incident from the first electrode 23 side to efficiently generate carriers in the lower active layer 31 of the photodiode PD. Furthermore, carriers are generated according to the light L1 transmitted through the lower active layer 31 and the second electrode 24 and applied to the upper active layer 34.

### Second Embodiment

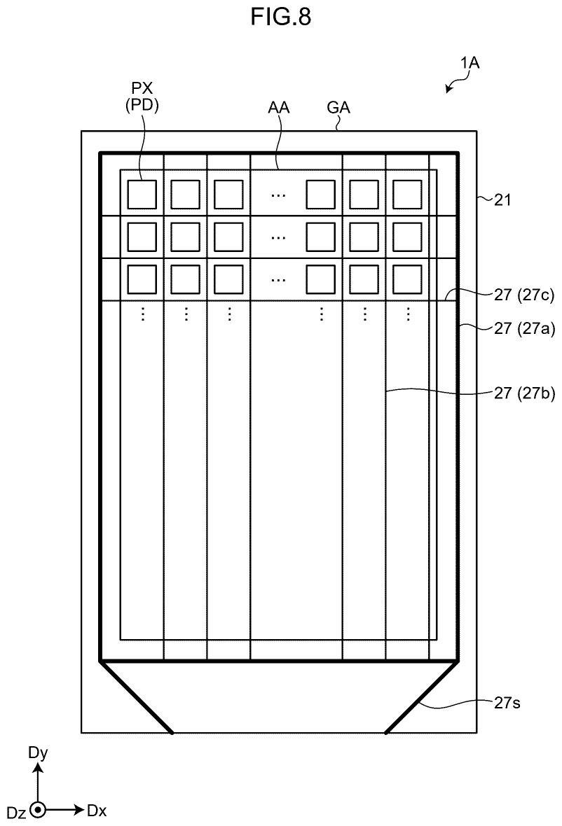

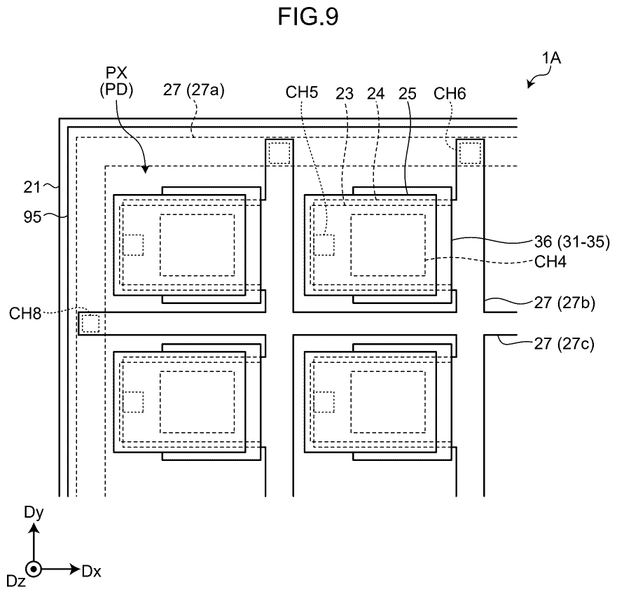

FIG. 8 is a plan view schematically illustrating the photodiodes and the potential supply wiring of a detection device according to a second embodiment of the present disclosure. FIG. 9 is an enlarged plan view illustrating some of the photodiodes and a portion of the potential supply wiring in FIG. 8. In the following description, the same components as those described in the embodiment above are denoted by the same reference numerals, and the description thereof will not be repeated.

As illustrated in FIGS. 8 and 9, in a detection device 1A according to the second embodiment, the potential supply wiring 27 includes the peripheral line 27a, the first extension lines 27b, second extension lines 27c, and the coupling lines 27s. The second extension lines 27c each extend in the first direction Dx and intersect the first extension lines 27b. The second extension lines 27c are coupled to the second electrodes 24 of the photodiodes PD arranged in the first direction Dx. One end and the other end in the first direction Dx of each of the second extension lines 27c are coupled to respective portions of the peripheral line 27a extending in the second direction Dy in the peripheral area GA.

As illustrated in FIG. 9, the second extension line 27c is formed in the same layer and of the same material as the first extension line 27b. The second extension line 27c is coupled to the peripheral line 27a through a contact hole CH8.

In the present embodiment, the predetermined potential (sensor power supply signal VDDSNS) is supplied to the photodiodes PD via the first extension lines 27b and the second extension lines 27c of the potential supply wiring 27. This configuration can more reduce variations in the predetermined potential supplied to the photodiodes PD than in the configuration not provided with the second extension lines 27c. For example, providing the second extension lines 27c can reduce the variations in the predetermined potential, between the photodiodes PD coupled to central portions of the first extension lines 27b and the photodiodes PD coupled to end sides of the first extension lines 27b.

The configuration of the potential supply wiring 27 is not limited to that illustrated in FIG. 8. For example, the potential supply wiring 27 may be configured with the second extension lines 27c and without the first extension lines 27b.

### Third Embodiment

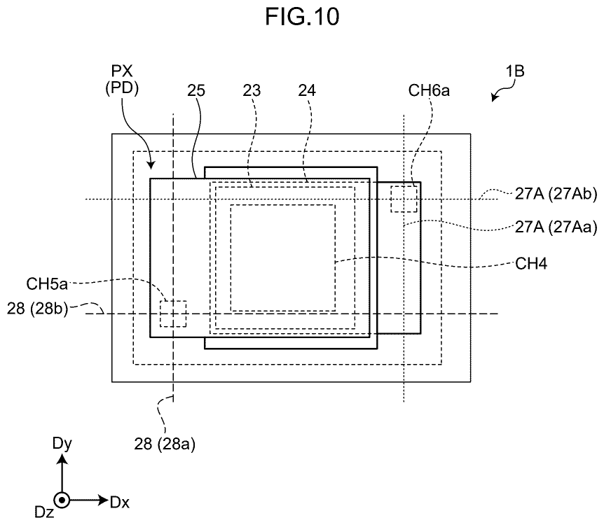

FIG. 10 is a plan view schematically illustrating the photodiode and potential supply wiring of a detection device according to a third embodiment of the present disclosure. As illustrated in FIG. 10, a detection device 1B according to the third embodiment includes potential supply wiring 27A that supplies a predetermined potential to the second electrode 24 and potential supply wiring 28 that supplies a predetermined potential to the third electrode 25.

The potential supply wiring 27A includes a first extension 27Aa and a second extension 27Ab in the same way as in the second embodiment described above, and is electrically coupled to the second electrode 24 through a contact hole CH6a. The potential supply wiring 28 includes a first extension 28a and a second extension 28b. The first extension 28a extends in the second direction Dy. The second extension 28b extends in the first direction Dx. The potential supply wiring 28 is electrically coupled to the third electrode 25 through a contact hole CH5a.

The predetermined potential supplied to the third electrode 25 only needs to be such a potential as to apply a reverse bias voltage to the upper active layer 34 between the third electrode 25 and the second electrode 24. The predetermined potential supplied to the third electrode 25 may be a voltage signal having the same potential as the sensor reference voltage COM supplied to the first electrode 23 or a voltage signal different from the sensor reference voltage COM.

The potential supply wiring 27A may be provided with only either the first extension 27Aa or the second extension 27Ab. The potential supply wiring 28 may be provided with only either the first extension 28a or the second extension 28b.

### Fourth Embodiment

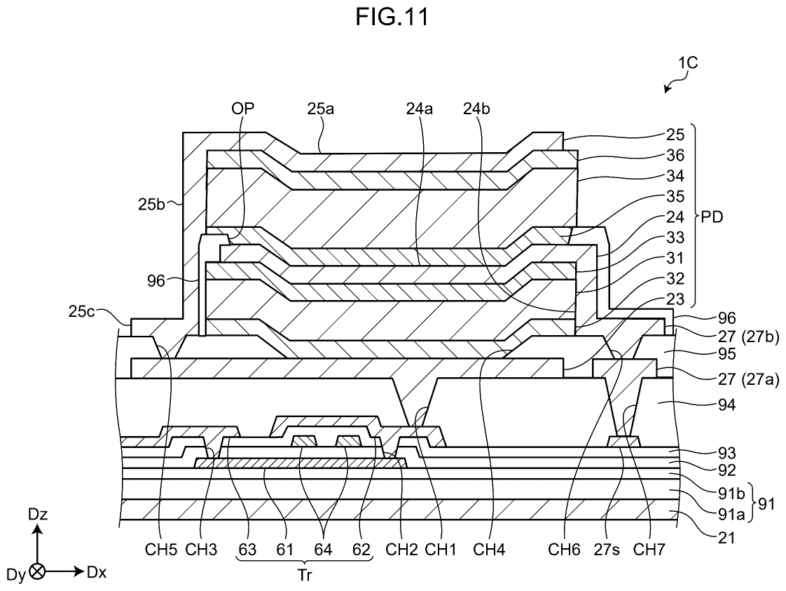

FIG. 11 is a plan view illustrating a detection device according to a fourth embodiment of the present disclosure. As illustrated in FIG. 11, a detection device 1C according to the fourth embodiment includes an insulating film 96 covering an outer edge of the second electrode 24. In more detail, the insulating film 96 is provided on the upper surface of the second electrode 24 and has an opening OP in an area overlapping the interlayer 24a of the second electrode 24 in plan view. The third buffer layer 35 is in contact with the upper surface of the second electrode 24 through the opening OP in the insulating film 96.

The insulating film 96 is provided so as to further cover a side surface of the first buffer layer 32, the lower active layer 31, and the second buffer layer 33. That is, the insulating film 96 is located between the side 25b of the third electrode 25 and the side surface of each of the first buffer layer 32, the lower active layer 31, and the second buffer layer 33. The insulating film 96 is provided between the second buffer layer 33 and the third buffer layer 35 in an area between a side surface of the interlayer 24a of the second electrode 24 and the side 25b of the third electrode 25.

Furthermore, the insulating film 96 is provided so as to cover the side 24b of the second electrode 24 and the first extension line 27b of the potential supply wiring 27.

This configuration of the fourth embodiment can prevent contact between the interlayer 24a of the second electrode 24 and the side 25b of the third electrode 25. Even when the overlapping portion 25a of the third electrode 25 is formed so as to extend more outward than the side surfaces of the third buffer layer 35, the upper active layer 34, and the fourth buffer layer 36, the overlapping portion 25a of the third electrode 25 can be prevented from contacting the side 24b of the second electrode 24.

The present embodiment is not limited to the example illustrated in FIG. 11, and other insulating films may be provided as required. For example, an insulating film may be provided to protect the side surfaces of the third buffer layer 35, the upper active layer 34, and the fourth buffer layer 36.

While the preferred embodiments of the present disclosure have been described above, the present disclosure is not limited to the embodiments described above. The content disclosed in the embodiments is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiments described above and modifications thereof.

What is claimed is:

1. A detection device comprising:
a substrate; and
a plurality of photodiodes in each of which a first electrode, a first buffer layer, a lower active layer, a second buffer layer, a second electrode, a third buffer layer, an upper active layer, a fourth buffer layer, and a third electrode are stacked on the substrate in the order as listed, wherein
the first electrode and the third electrode of the photodiode are electrically coupled to each other,
each of the first buffer layer and the fourth buffer layer is one of a hole transport layer and an electron transport layer, and
each of the second buffer layer and the third buffer layer is the other of the hole transport layer and the electron transport layer.

2. The detection device according to claim 1, comprising an insulating film covering an outer edge of the second electrode.

3. The detection device according to claim 1, comprising a plurality of gate lines and a plurality of signal lines provided on the substrate, wherein
the photodiodes are arranged in a matrix having a row-column configuration in a detection area of the substrate, and
each of the photodiodes is located in an area surrounded by the signal lines and the gate lines.

4. The detection device according to claim 1, comprising:
a plurality of drive transistors provided on the substrate and coupled to the respective photodiodes;
gate lines and signal lines coupled to the drive transistors; and
potential supply wiring provided on the substrate and configured to supply a predetermined potential to the photodiodes, wherein
the first electrode and the third electrode are coupled to a corresponding one of the drive transistors, and
the second electrode is coupled to the potential supply wiring.

5. The detection device according to claim 1, wherein a thickness of the upper active layer differs from a thickness of the lower active layer.

6. The detection device according to claim 1, wherein
the third electrode has a light-transmitting property, and
a thickness of the upper active layer is larger than a thickness of the lower active layer.

7. The detection device according to claim 1, wherein
the first electrode has a light-transmitting property, and
a thickness of the lower active layer is larger than a thickness of the upper active layer.

8. The detection device according to claim 4, wherein the potential supply wiring is provided in a peripheral area of the substrate so as to surround a detection area of the substrate.
